(19) United States
(12) Patent Application Publication
(10) Pub. No.: US 2012/0327579 A1
(43) Pub. Date: Dec. 27, 2012

(54) COMPUTER CHASSIS FOR MOUNTING MOTHERBOARD THEREIN

(75) Inventors: Yun-Lung CHEN, Tu-Cheng (TW); Liang-Chin WANG, Tu-Cheng (TW); Jian HU, Wuhan City (CN); Yu-Ming XIAO, Wuhan City (CN); Wei YIN, Wuhan City (CN)

(73) Assignees: HON HAI PRECISION INDUSTRY CO., LTD., Tu-Cheng (TW); HONG FU JIN PRECISION INDUSTRY (WuHan) CO., LTD., Wuhan City (CN)

(21) Appl. No.: 13/425,385

(22) Filed: Mar. 20, 2012

(30) Foreign Application Priority Data
Jun. 22, 2011 (CN) 201110168809.1

(51) Int. Cl. H05K 7/14

(52) U.S. Cl. 361/679.6

(57) ABSTRACT

A computer chassis includes an enclosure and a motherboard. The enclosure includes a bottom plate and a rear plate. A plurality of convex projections is located on the bottom plate. Each of the plurality of convex projections defines a first mounting hole. A first restricting piece is located on the bottom plate. The motherboard defines a plurality of second mounting holes. The motherboard is located on the plurality of convex projections and between the rear plate and the first restricting piece with a front edge of the motherboard abutting the first restricting piece and a rear edge of the motherboard abutting the rear plate. The plurality of second mounting holes of the motherboard is aligned to the first mounting holes of the plurality of convex projections.

### BACKGROUND

1. Technical Field

The present disclosure relates to a computer chassis, more particularly, to a computer chassis on which a motherboard can be conveniently mounted.

2. Description of Related Art

Many motherboards can only be mounted in a computer chassis with fasteners, such as screws or bolts. However, it can be difficult and time consuming to properly align securing holes of the motherboard with securing holes of the computer chassis.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded and isometric view of an embodiment of a computer chassis and a motherboard.

FIG. 2 is an isometric view of the computer chassis of FIG. 1.

FIG. 3 is an enlarged view of the encircled portion III of FIG. 2.

FIG. 4 is an enlarged view of the encircled portion IV of FIG. 2.

FIG. 5 is an assembled view of the computer chassis of FIG. 1.

FIG. 6 is another assembled view of the computer chassis of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

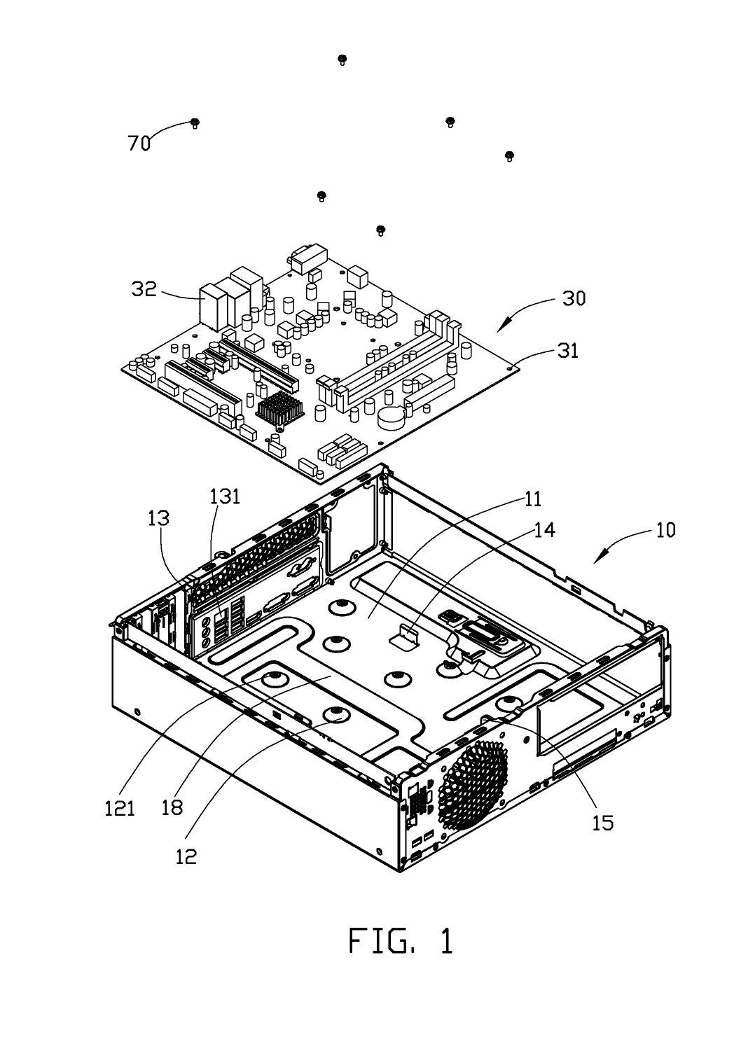

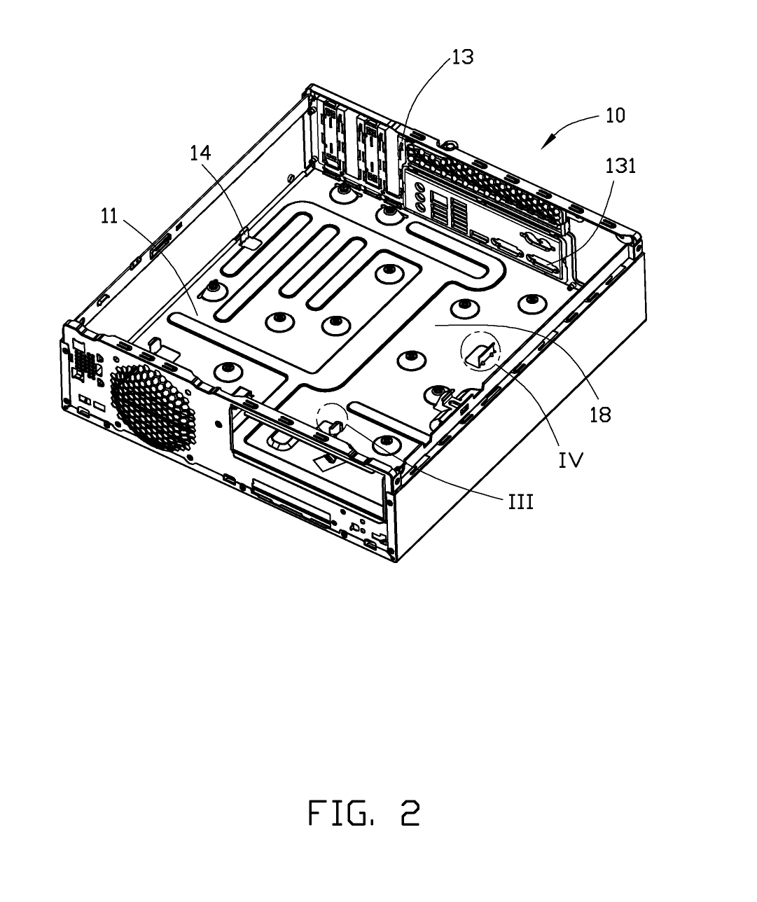

Referring to FIGS. 1 and 2, a computer chassis for mounting a motherboard 30 therein, includes an enclosure 10.

The enclosure 10 includes a bottom plate 11 and a rear plate 13. The rear plate 13 is perpendicularly connected to a rear edge of the bottom plate 11. A plurality of convex projections 12 is protruded from the bottom plate 11. Each of the plurality of convex projections 12 defines a first mounting hole 121. The plurality of convex projections 12 can support the motherboard 30 thereon. The bottom plate 11 further includes a plurality of first restricting pieces 15 and a plurality of second restricting pieces 14 located thereon. The plurality of first restricting pieces 15, the plurality of second restricting pieces 14, and the rear plate 13 together surround a mounting area 18 on the bottom plate 11. The plurality of first restricting pieces 15 and the rear plate 13 are located on opposite two edges of the mounting area 18. The plurality of second restricting pieces 14 are located on another opposite two edges of the mounting area 18. The plurality of convex projections 12 are located in the mounting area 18.

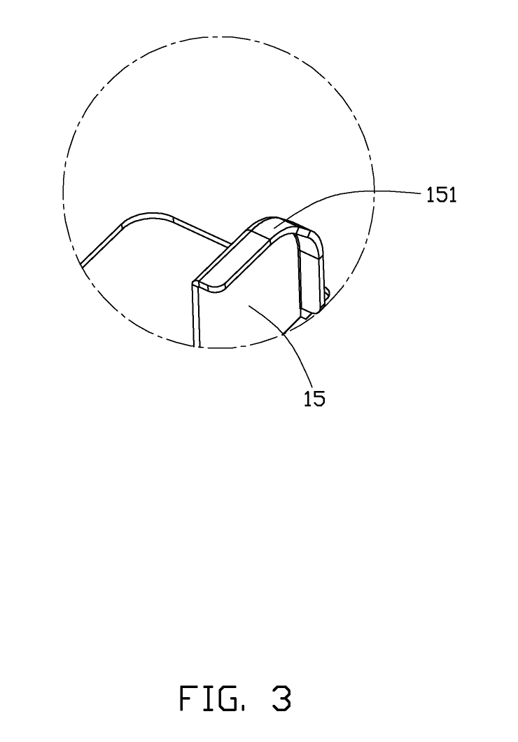

Referring to FIGS. 2 and 3, each of the plurality of first restricting pieces 15 is perpendicularly connected to the bottom plate 11. An edge of each of the plurality of first restricting pieces 15 which faces the mounting area 18 is rounded, and an arc-shaped first guiding piece 151 is connected to the rounded edge. The first guiding piece 151 is perpendicular to each of the plurality of first restricting pieces 15.

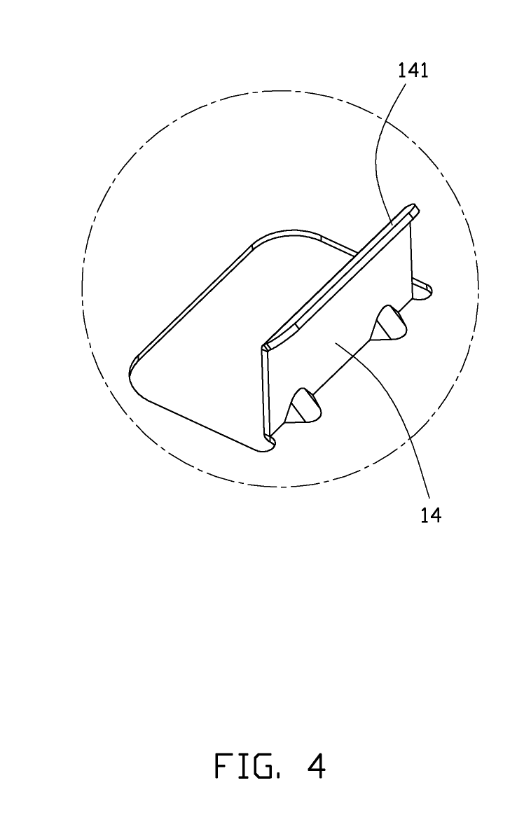

Referring to FIGS. 2 and 4, each of the plurality of second restricting pieces 14 is perpendicularly connected to the bottom plate 11. A top edge of each of the plurality of second restricting pieces 14 is bent away from the mounting area 18 to form a second guiding piece 141 thereon. The second guiding piece 141 is arc-shaped.

Referring to FIGS. 1 and 2, the rear plate 13 defines a plurality of cutouts 131.

The rear edge of the motherboard 30 is equipped with a plurality of ports 32. A plurality of second mounting holes 31 is defined in the motherboard 30 corresponding to the first mounting holes 121 of the bottom plate 11.

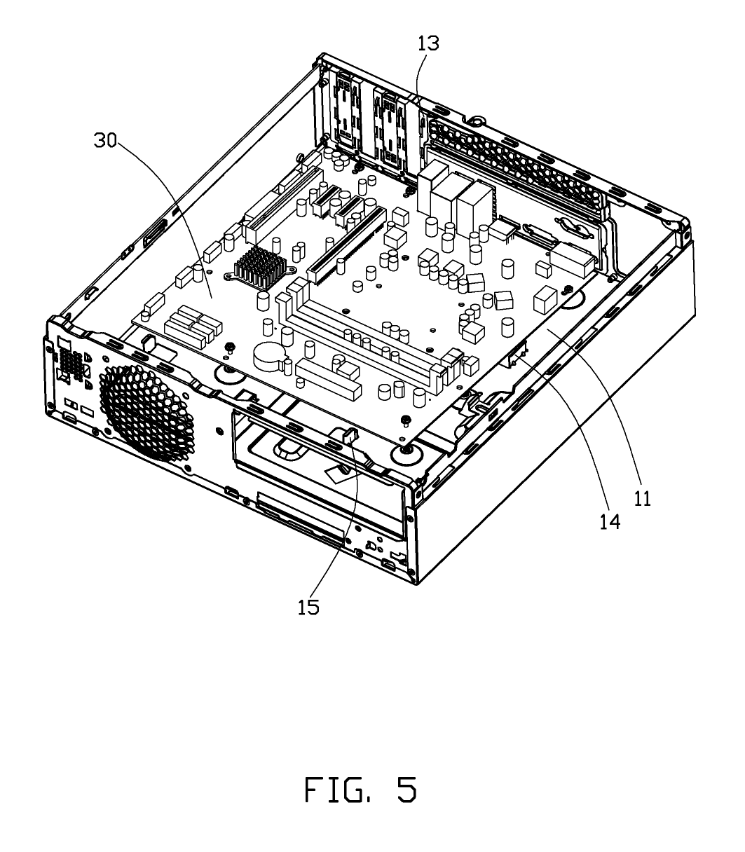

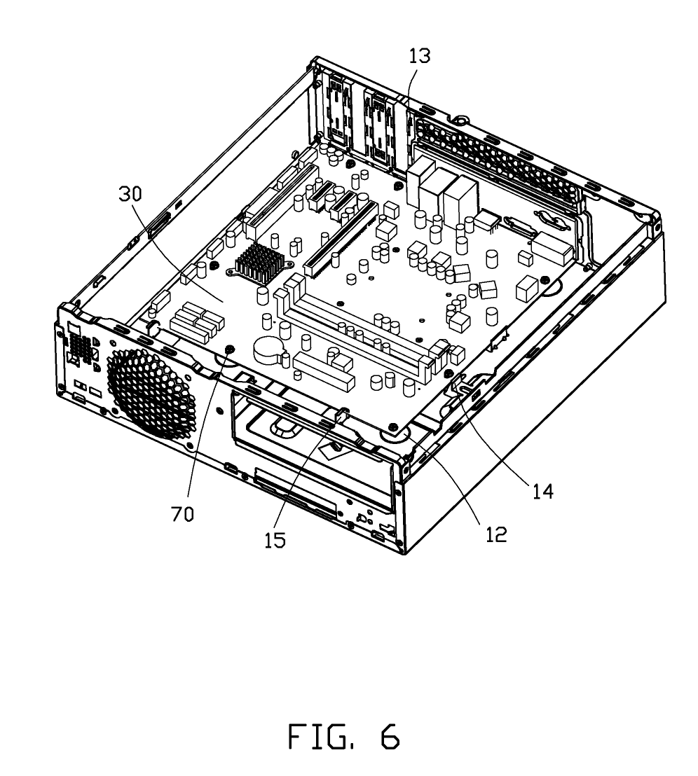

Referring to FIGS. 1 to 6, to mount the motherboard 30 in the enclosure 10, the rear edge of the motherboard 30 is inclined to align the plurality of ports 32 with the plurality of the cutouts 131 of the rear plate 13. Then, the motherboard 30 is rotated around the rear edge while left and right edges of the motherboard 30 slide along the second guiding pieces 141 of the plurality of second positioning pieces 14. The front edge of the motherboard 30 slides along the first guiding piece 151 of each of the plurality of first restricting pieces 15. The motherboard 30 is rotated until the plurality of convex projections 12 support the motherboard 30 thereon. At this position, the rear edge of the motherboard 30 abuts the rear plate 13. The front edge of the motherboard 30 abuts the plurality of first restricting pieces 15. The left and right edges of the motherboard 30 abut the plurality of second restricting pieces 14. The plurality of second mounting holes 31 of the motherboard 30 are aligned to the first mounting holes 121. Then, a plurality of fasteners 70 can be easily secured in the plurality of second mounting holes 31 and the first mounting holes 121 to secure the motherboard 30 in the enclosure 10.

In the computer chassis, the first guiding piece 151 and the second guiding piece 141 can guide the motherboard 30 to slide into the correct position where the plurality of first restricting pieces 15 and the plurality of second restricting pieces 14 can conveniently keep the motherboard 30 in the correct position where the first mounting holes 121 and the plurality of second mounting holes 31 are aligned, while fasteners are installed. The first guiding piece 151 and the second guiding piece 141 are arc-shaped to prevent scratching the motherboard 30.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the invention to the full extent indicated by the broad general meaning of the terms in which the appended claims are expressed.

What is claimed is:

1. A computer chassis, comprising:
an enclosure comprising a bottom plate and a rear plate, a plurality of convex projections located on the bottom plate, each of the plurality of convex projections defining a first mounting hole, a first restricting piece located on the bottom plate; and
a motherboard defining a plurality of second mounting holes, the motherboard being located on the plurality of convex projections and between the rear plate and the first restricting piece with a front edge of the motherboard abutting the first restricting piece and a rear edge of the motherboard abutting the rear plate, and each of the plurality of second mounting holes being aligned with the first mounting hole.

2. The computer chassis of claim 1, wherein the first restricting piece comprises a first guiding piece adapted to guide the front edge of the motherboard to abut the first restricting piece.

3. The computer chassis of claim 2, wherein the first restricting piece is perpendicularly connected to the bottom plate, a first edge of the first restricting piece facing the motherboard is rounded, and the first guiding piece is perpendicularly connected to the first edge.

4. The computer chassis of claim 1, wherein a plurality of ports are formed on the rear edge of the motherboard, the rear plate defines a plurality of cutouts, and each of the plurality of ports is aligned with each of the plurality of the cutouts.

5. The computer chassis of claim 1, wherein a plurality of second restricting pieces is located on the bottom plate, the first restricting piece, the rear plate, and the plurality of second restricting pieces together surround a mounting area on the bottom plate, the first restricting piece and the rear plate are located on opposite two edges of the mounting area, the plurality of second restricting pieces are located on another opposite two edges of the mounting area, and the plurality of convex projections are located in the mounting area.

6. The computer chassis of claim 5, wherein a left edge and a right edge of the motherboard abut the plurality of second restricting pieces.

7. The computer chassis of claim 6, wherein a second guiding piece is formed on a top edge of each of the plurality of second restricting pieces by bending each of the plurality of second restricting pieces away from the mounting area, and the second guiding piece is adapted to guide the left or the right edge of the motherboard to abut each of the plurality of second restricting pieces.

8. The computer chassis of claim 5, wherein each of the plurality of second restricting pieces is perpendicularly connected to the bottom plate.

9. A computer chassis, comprising:
an enclosure comprising a bottom plate and a rear plate, a plurality of convex projections located on the bottom plate, each of the plurality of convex projections defining a first mounting hole, a plurality of first restricting piece located on the bottom plate; and
a motherboard defining a plurality of second mounting holes, the motherboard being located on the plurality of convex projections and among the rear plate and the plurality of first restricting pieces with a rear edge of the motherboard abutting the rear plate and a left edge and a right edge of the motherboard abutting the plurality of first restricting pieces, and each of the plurality of second mounting holes being aligned to the first mounting hole.

10. The computer chassis of claim 9, wherein a second restricting piece is located on the bottom plate, the plurality of first restricting pieces, the rear plate, and the second restricting piece together surround a mounting area on the bottom plate, the second restricting piece and the rear plate are located on opposite two edges of the mounting area, the plurality of first restricting pieces are located on another opposite two edges of the mounting area, and the plurality of convex projections are located in the mounting area.

11. The computer chassis of claim 10, wherein a first guiding piece is formed on a top edge of each of the plurality of first restricting pieces by bending each of the plurality of first restricting pieces away from the mounting area, and the first guiding piece is adapted to guide the left or the right edge of the motherboard to abut each of the plurality of first restricting pieces.

12. The computer chassis of claim 10, wherein a front edge of the motherboard abuts the second restricting piece.

13. The computer chassis of claim 12, wherein the second restricting piece comprises a second guiding piece adapted to guide the front edge of the motherboard to abut the second restricting piece.

14. The computer chassis of claim 13, wherein the second restricting piece is perpendicularly connected to the bottom plate, a first edge of the second restricting piece facing the motherboard is rounded, and the second guiding piece is perpendicularly connected to the first edge.

15. The computer chassis of claim 9, wherein a plurality of ports are formed on the rear edge of the motherboard, the rear plate defines a plurality of cutouts, and each of the plurality of ports is aligned with each of the plurality of the cutouts.

16. The computer chassis of claim 9, wherein each of the plurality of first restricting pieces is perpendicularly connected to the bottom plate.
